(19) United States
(12) Patent Application Publication
(10) Pub. No.: US 2012/0281487 A1
(43) Pub. Date: Nov. 8, 2012

(54) SEMICONDUCTOR MEMORY DEVICE AND METHOD OF CONTROLLING THE SAME

(76) Inventors: Manabu SAKANIWA, Yokohama-shi (JP); Koki Ueno, Yokohama-si (JP); Shigefumi Irieda, Yokohama-shi (JP); Eietsu Takahashi, Yokohama-shi (JP); Yasuhiro Shiino, Yokohama-shi (JP)

(21) Appl. No.: 13/288,485

(22) Filed: Nov. 3, 2011

(30) Foreign Application Priority Data
May 2, 2011 (JP) 2011-103216

(51) Int. Cl. G11C 7/22

(52) U.S. Cl. 365/189.16

(57) ABSTRACT

According to one embodiment, a semiconductor memory device includes a memory cell array includes a plurality of memory cell units which are arranged at intersections of a plurality of bit lines and a plurality of word lines and whose current paths are connected in series, a voltage generator circuit which generates a voltage to be applied to the memory cell array, and a control circuit which controls the memory cell array and the voltage generator circuit. The control circuit, when writing data into the memory cell array, performs control so as to apply a first write pass voltage to unselected word lines in the memory cell units and, after a selected word line has reached a write voltage, further apply a voltage to the unselected word lines until a second write pass voltage higher than the first write pass voltage has been reached.

### CROSS-REFERENCE TO RELATED APPLICATIONS

This application is based upon and claims the benefit of priority from prior Japanese Patent Application No. 2011-103216, filed May 2, 2011, the entire contents of which are incorporated herein by reference.

### FIELD

Embodiments described herein relate generally to a semiconductor memory device and a method of controlling the same.

### BACKGROUND

Of semiconductor memory devices, for example, a NAND flash memory comprises NAND cell units in each of which a plurality of current paths of memory cells are connected in series.

When data is written, a write pass voltage (VPASS) is applied to the unselected cells in the NAND cell units to form channels and a write voltage (VPGM) is applied to the selected cell, thereby writing a specific threshold value into the selected cell.

### BRIEF DESCRIPTION OF THE DRAWINGS

FIG. 1 is a block diagram showing an overall configuration of a semiconductor memory device according to a first embodiment;

FIG. 2 is a sectional view to explain voltage relations when data is written in the semiconductor memory device according to the first embodiment;

FIG. 3 is a timing chart to explain a data write operation in the semiconductor memory device of the first embodiment;

FIG. 4 shows the inclination of the rising of the voltage of an unselected word line in a data write operation in the semiconductor memory device of the first embodiment;

FIG. 5 shows an example of generating voltage waveforms in the semiconductor memory device of the first embodiment;

FIG. 6 shows the inclination of the rising of the voltage of an unselected word line in a data write operation in the semiconductor memory device of the first embodiment;

FIG. 7 shows voltage waveforms of an unselected word line in a data write operation in a semiconductor memory device of a comparative example;

FIG. 8 shows voltage waveforms of an unselected word line in a data write operation in the semiconductor memory device of the first embodiment;

FIG. 9 is a diagram to explain the number of failure bits after data is written in the semiconductor memory device of the first embodiment;

FIG. 10 is a sectional view to explain voltage relations (in an REASB method) when data is written in a semiconductor memory device according to a second embodiment;

FIG. 11 shows voltage waveforms of an unselected word line in a data write operation in a semiconductor memory device according to a third embodiment;

FIG. 12 shows voltage waveforms of an unselected word line in a data write operation in a semiconductor memory device according to a fourth embodiment;

FIG. 13 shows voltage waveforms of an unselected word line in a data write operation in a semiconductor memory device according to a fifth embodiment;

FIG. 14 shows voltage waveforms of an unselected word line in a data write operation in a semiconductor memory device according to a sixth embodiment; and

FIG. 15 is a flowchart to show the number of write loops.

### DETAILED DESCRIPTION

In general, according to one embodiment, a semiconductor memory device includes a memory cell array comprising a plurality of memory cell units which are arranged at intersections of a plurality of bit lines and a plurality of word lines and whose current paths are connected in series, a voltage generator circuit which generates a voltage to be applied to the memory cell array, and a control circuit which controls the memory cell array and the voltage generator circuit. The control circuit, when writing data into the memory cell array, performs control so as to apply a first write pass voltage to unselected word lines in the memory cell units and, after a selected word line has reached a write voltage, further apply a voltage to the unselected word lines until a second write pass voltage higher than the first write pass voltage has been reached.

As described above, when data is written into a NAND flash memory, a write pass voltage (VPASS) is applied to the unselected cells in the NAND cell units to form channels and a write voltage (VPGM) is applied to the selected cell, thereby writing a specific threshold value into the selected cell.

However, a write stress increases due to the magnitude and duration of a write pass voltage (VPASS) applied to the unselected cells, which might cause write failures.

Hereinafter, embodiments will be explained concretely with reference to the accompanying drawings. While in the explanation, a NAND flash memory is used as an example of a semiconductor memory device, the invention is not limited to this. In the explanation, like parts throughout the drawings are indicated by the same reference numerals.

### First Embodiment

<1. Overall Configuration>

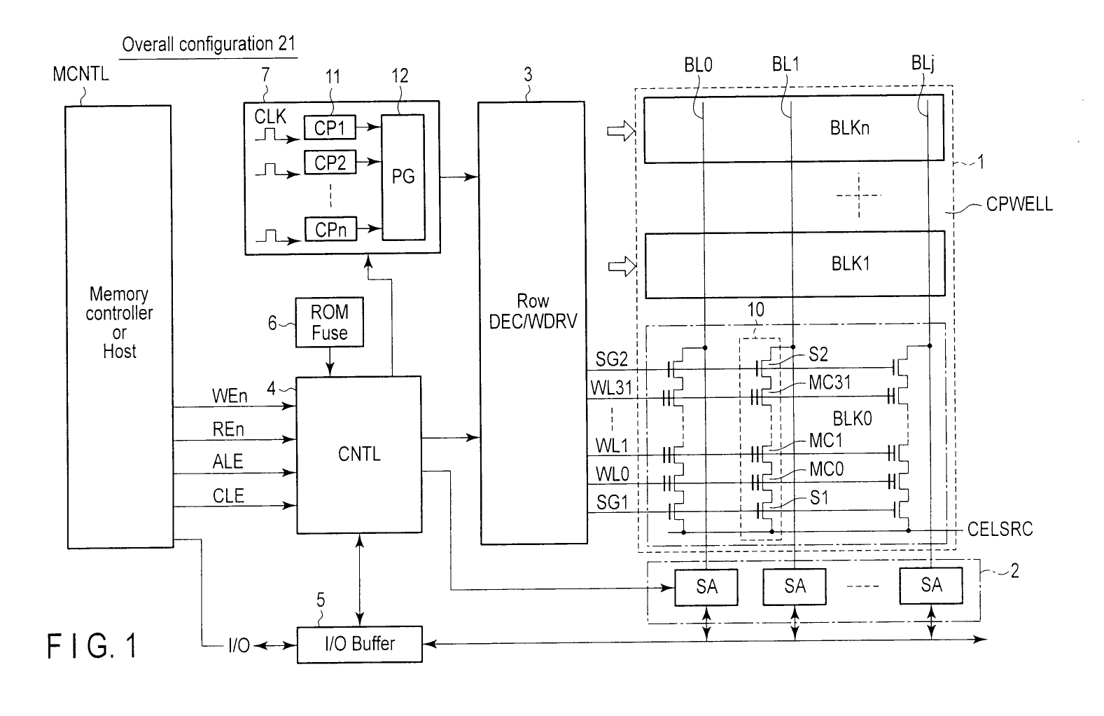

An overall configuration of a semiconductor memory device according to a first embodiment will be explained with reference to FIG. 1.

As shown in FIG. 1, a NAND flash memory 21 of the first embodiment comprises a memory cell array 1, a sense amplifier circuit 2, a row decoder 3, a controller 4, an input/output buffer 5, a ROM fuse 6, and a voltage generator circuit 7. The controller 4 constitutes a control module for the memory cell array 1.

The memory cell array 1 is composed of a plurality of blocks (BLK0, BLK1, . . . , BLKn) in each of which NAND cell units 10 are arranged in a matrix. A NAND cell unit 10 is composed of memory cells MCs (MC0, MC1, . . . , MC31) whose current paths are connected in series and select gate transistors S1, S2 each connected to either end of the series connection of the memory cells MCs.

Although not shown, a memory cell MC has a floating gate electrode acting as a charge storage layer on a gate insulating film (tunnel insulating film) formed between a drain and a source, with a control gate electrode formed above the floating gate electrode via an inter-gate insulating film. The control gate is connected to one of the word lines.

The source of the select gate transistor S1 is connected to a common source line CELSRC and the drain of the select gate transistor S2 is connected to a bit line BL.

The control gates of the memory cells MCs in a NAND cell unit 10 are connected to different word lines WLs (WL0, WL1, . . . , WL31) in a one-to-one correspondence. The gates of the select gate transistors S1, S2 are connected to select gate lines SG1, SG2 in parallel with word lines WL. A set of memory cells sharing a word line constitutes one page or two pages. A set of NAND cell units sharing word lines WL and select gate lines SG1, SG2 constitutes a block BLK serving as a unit of data erasing. The memory cell array 1 including a plurality of blocks (BLK0, BLK1, . . . , BLKn) is formed in a cell well (CPWELL) of a silicon substrate.

The sense amplifier circuit (SA) 2 is connected electrically to bit lines BL of the memory cell array 1. The sense amplifier circuit 2 comprises a plurality of sense amplifiers SA constituting a page buffer for sensing read data and holding write data. The sense amplifier circuit 2 includes column select gates.

The row decoder (including a word line driver) (RowDED/WDRV) 3 selects a word line WL and select gate lines SG1, SG2 and drives them.

The controller (CNTL) 4 receives external control signals, including a write enable signal WEn, a read enable signal REn, an address latch enable signal ALE, and a command latch enable signal CLE, and controls an overall operation of the NAND flash memory 21. These signals are transmitted from a memory controller MCNTL.

Specifically, the controller 4, which includes a command interface and an address holding and transfer circuit, determines whether the supplied data is write data or address data. Depending on the determination result, the write data is transferred to the sense amplifier circuit 2 and the address data is transferred to the row decoder 3 and sense amplifier circuit 2. In addition, on the basis of an external control signal, the controller 4 performs sequence control of data reading, data writing, and data erasing and control of applied voltages.

The data input/output buffer (I/O buffer) 5 not only performs the exchange of data between the sense amplifier circuit 2 and external input/output terminals but also receives command data and address data. These signals are also transmitted from the memory controller MCNTL.

In the ROM fuse 6, for example, parameters and others related to write voltage levels used in a data write operation are recorded. They are read from, for example, the ROM fuse 6 when the power supply of the NAND flash memory 21 is turned on and loaded into a register circuit (not shown) in the controller 4. They are used when, for example, the NAND flash memory 21 operates.

The voltage generator circuit 7 comprises step-up circuits 11 and a pulse generator circuit 12. Each of the step-up circuits 11 is composed of a plurality of charge pump circuits (CP1, CP2, . . . , CPn). Each step-up circuit 11 charges a specific voltage according to a clock CLK supplied by a clock generator circuit (not shown) and outputs the voltage to the pulse generator circuit. The pulse generator circuit (PG) 12 generates a desired pulse voltage necessary for data read operations according to the input from the step-up circuits 11.

With this configuration, the voltage generator circuit 7 changes the number of clocks in an input clock CLK and the number of step-up circuits 11 to be driven according to a control signal from the controller 4 and controls the pulse generator circuit 12, thereby generating a desired pulse voltage. The reason why the number of clocks in the clock CLK and the number of step-up circuits 11 to be driven are changed is to change the rise time of a pulse voltage (or the degree of dullness of the inclination of a voltage waveform) as described later.

<2. Data Write Operation>

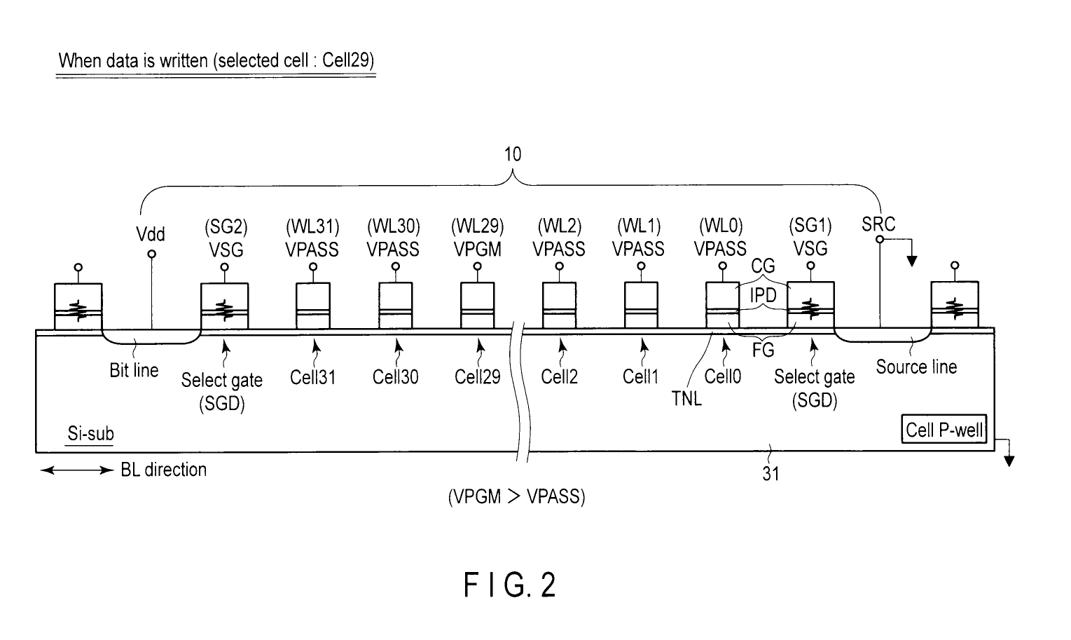

Next, a data write operation in the semiconductor memory device of the first embodiment will be explained with reference to FIGS. 2 to 6.

2-1. Voltage Relations in a Data Write Operation

FIG. 2 shows voltage relations when data is written into a NAND cell unit 10. As shown in FIG. 2, each of memory cells MC0 to MC31 and select gates SGS, SGD comprises a tunnel insulating film, a charge storage layer (floating electrode) FG, an inter-gate insulating film IPD, and a control gate CG which are provided sequentially on a well of the semiconductor substrate. An opening is made in the central part of the inter-gate insulating film IPD of each of the select gates SGS, SGD, thereby causing the floating electrode FG and control electrode CG to be electrically connected to each other.

With this configuration, the voltage relations in a data write operation are as follows. Suppose the selected cell is memory cell MC29.

A write voltage VPGM is applied to the selected word line WL29 connected to the selected cell MC29.

A write pass voltage VPASS is applied to unselected word lines WL0 to WL28 and WL30 and WL31 of the unselected cells MC0 to MC28 and MC30 and MC31. The write pass voltage VPASS is applied, forming the channels of the unselected cells MC0 to MC28 and MC30 and MC31, which causes a current path to conduct. The write pass voltage VPGM is higher than the write pass voltage VPASS (VPG>VPASS).

A select voltage VSG is applied to select gates SGS, SGD.

When the selected cell is to be written into, for example, the ground potential Vss is applied to the bit line. When the selected cell is not to be written into, for example, an internal power supply voltage Vdd is applied to the bit line.

A source voltage SRC is applied to a source line.

A specific well voltage is applied to a well (Cell P-well) in the semiconductor substrate. The potential of the channel of a cell not to be written into is called a channel potential. As the channel potential is closer to the write voltage VPGM, the selected cell not to be written into is less liable to be written into erroneously.

2-2. Timing Chart for a Data Write Operation

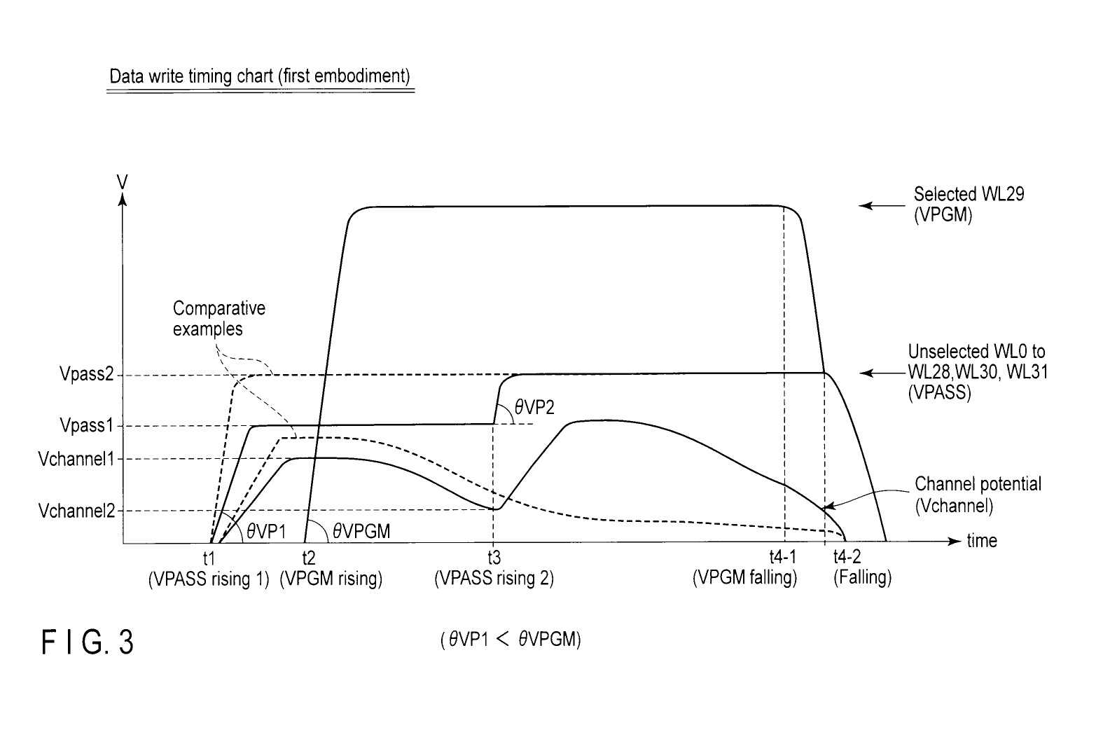

Next, a data write operation will be explained in more detail with reference to the timing chart of FIG. 3. In this operation, overall control is performed by the controller 4. FIG. 3 shows a case where the selected cell is not to be written into, that is, a case where the channel potential of the NAND cell unit 10 is raised by so-called self-boosting.

First, for example, a select voltage is applied to the select gates SGS, SGD shown in FIG. 2 and, for example, an internal power supply voltage Vdd is applied to bit line BL.

At time t1, a write pass voltage VPASS1 is applied to the unselected word lines WL0 to WL28 and WL30 and WL31 and the substrate. After the voltages of the unselected word lines WL0 to WL28 and WL30 and WL31 have reached the write pass voltage VPASS1, the channel potential of the NAND cell unit 10 is raised to Vchannel1 by self-boosting. At this time, the rising of the write pass voltage VPASS has an inclination of θVP1. The inclination θVP1 is smaller than the inclination θVPGM of the write voltage (θVP1<θVPGM).

At time t2, the write voltage VPGM is applied to the selected word line WL29. In this case, the rising of the write voltage VPGM has an inclination of θVPGM. At this time, the channel potential of the NAND cell unit 10 might rise from Vchannell as a result of self-boosting. In the first embodiment, to simplify the explanation, suppose Vchannell does not fluctuate.

The channel potential drops due to a leak, such as a junction leak or an off-leak of the select gate transistor. Hereinafter, a leak that causes the channel potential to drop is referred to as a boost leak.

At time t3, charges are injected into the charge storage layer of the selected cell to be written into by a high electric field between the control electrode CG and channel. On the other hand, the channel potential of the selected cell not to be written into drops to Vchannel2 due to a boost leak. Here, the voltages of the unselected word lines WL0 to WL28 and WL30 and WL31 are raised to a second write pass voltage VPASS2. At this time, the rising of the write pass voltage VPASS has an inclination of θVP2. As shown in FIG. 3, raising the voltages to the second write pass voltage VPASS2 enables the channel potential Vchannel2 dropped due to a boost leak to be raised again by coupling. Therefore, in a write operation, the substrate voltage Vchannel of the selected memory cell not to be written into can be caused to remain high. Time t3 may lie in the middle of the rising of the write voltage VPGM. It is because, even if time t3 lies in the middle of the rising of the write voltage VPGM, the channel potential can be raised by raising the write pass voltage.

When there is no need to distinguish between the write pass voltages VPASS1 and VPASS2, they may be referred to as the write voltage VPASS.

Thereafter, at time t4-1, the potential of the selected word line is lowered to the write pass voltage VPASS2 temporarily and then the potential of the word line WL is lowered (time t4-2). The channel potential Vchannel falls by coupling at the same time when the potential of the word line is lowered.

The above cycle is repeated until the selected cell MC29 to be written into has reached a specific threshold voltage.

In contrast, in comparative examples shown by broken lines in FIG. 3, control is not performed so as to make smaller the inclination of the rising of the write pass voltage of the unselected word line than the inclination of the write voltage of the selected word line WL. In addition, after the write voltage has risen, the write pass voltage is not raised. That is, the write pass voltage VPASS2 in the second stage is not applied. Therefore, the channel potentials in the comparative examples do not rise after the voltage of the selected word line has risen.

As described above, in the first embodiment, control is performed so as to make smaller the inclinations θVP1, θVP2 of the rising of the write pass voltage VPASS than the inclination θVPGM of the rising of the write voltage (θVP1, θVP2>θVPGM) in comparison with the comparative examples shown by broken lines. Therefore, as compared with the comparative examples (where the inclination of the rising of the write pass voltage is large), an area of write pass voltage VPASS×time can be decreased. Accordingly, a write stress on the unselected cell can be reduced, which is helpful in reducing write failures.

In addition, in the first embodiment, at time t3, the voltages of the unselected word lines WL0 to WL28 and WL30 and WL31 are raised to a second write pass voltage VPASS2 which has an inclination of θVP2. Therefore, applying the second write pass voltage VPASS2 causes the channel potential Vchannel2 dropped due to a boost leak to rise again by coupling. Accordingly, the substrate voltage Vchannel can be caused to remain at a high voltage.

2-3. Inclination of the Rising of a Voltage

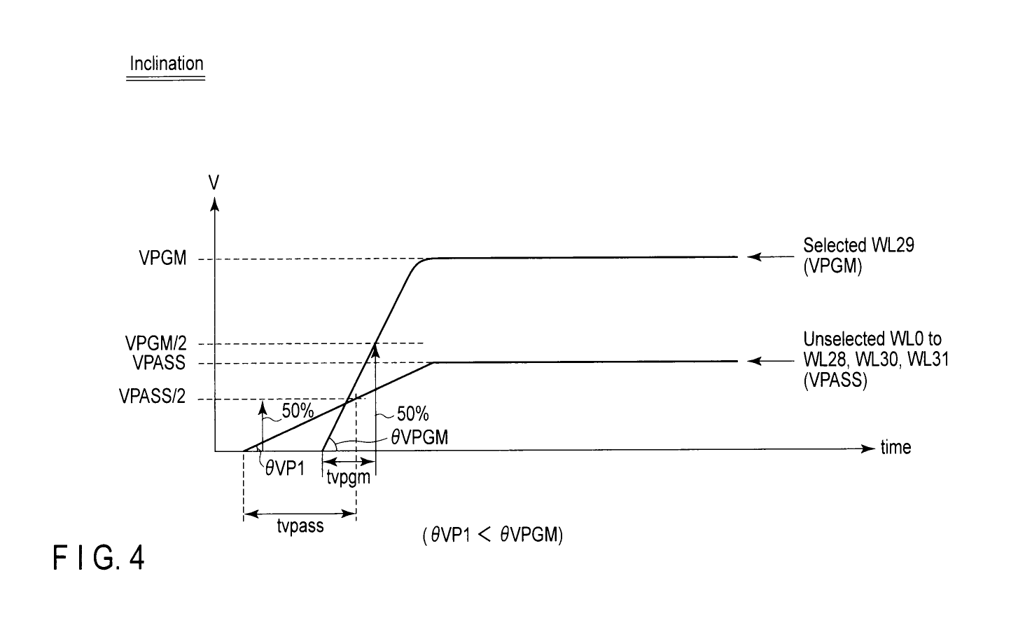

Next, the inclination of the rising of a voltage in the first embodiment will be explained with reference to FIG. 4.

As shown in FIG. 4, the inclination θVP1 of the write pass voltage VPASS and the inclination θVPGM of the write voltage VPGM are defined as follows:

The inclination of the rising of a voltage: the time required to reach 50% of the maximum voltage

Specifically, what are shown in FIG. 4 are as follows:

The inclination θVP1 of write pass voltage VPASS: (VPASS1/2)/tvpass

The inclination θVPGM of write voltage VPGM: (VPGM/2)/tvpgm

In the first embodiment, control is performed so as to make smaller the inclination θVP1 of the rising of write pass voltage VPASS1 than the inclination θVPGM of the rising of the write voltage (θVP1<θVPGM). The write pass voltage VPASS starts to be raised earlier than or simultaneously with the write voltage VPGM.

2-4. Generation of Inclinations θVP1, θVP2

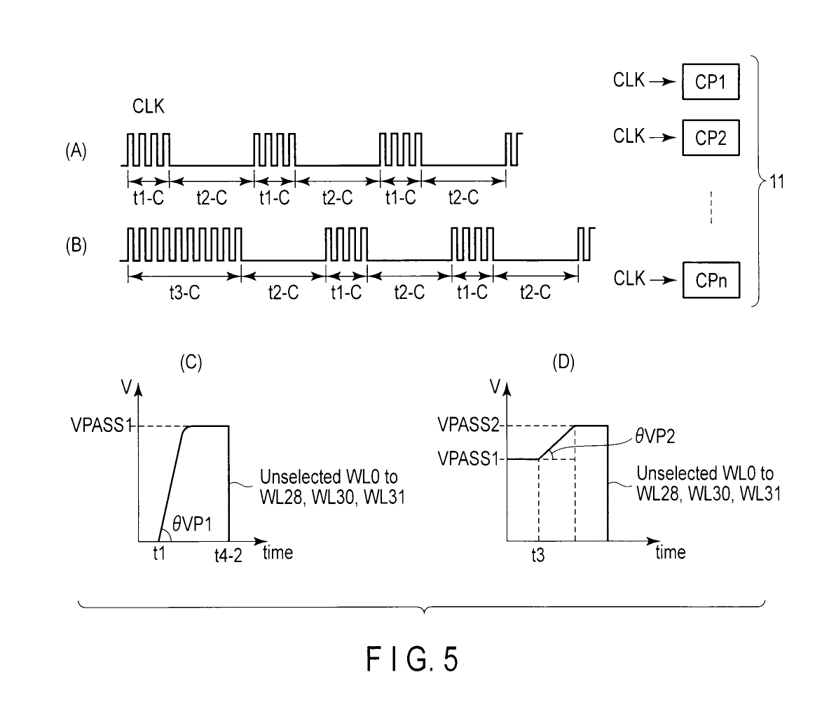

Next, the generation of the inclinations θVP1, θVP2 of the write pass voltage VPASS according to the first embodiment will be explained with reference to FIG. 5.

First, to obtain output waveform (C) in FIG. 5, clock pulses CLK to be input to the charge pump circuits (CP1 to CPn) 11 are generated consecutively during period t1-C as shown in clock waveform (A) of FIG. 5, causing the charge pump circuits 11 to operate to continue a step-up operation.

Then, during period t2-C, clock pulses CLK to be input to the charge pump circuits (CP1 to CPn) 11 are stopped, causing the step-up operation to stop.

From the beginning of the rising of the voltage VPASS, the step-up operation is repeated during periods t1-C and t2-C until a voltage VPASS1 is obtained. As a result, a blunt waveform whose rising has an inclination of θVP1 and an inclination of θVP2 shown by output waveform (C) can be generated on the unselected word lines WL0 to WL28 and WL30 and WL31. In the first embodiment, the number of clocks during period t1-C is made smaller (or the frequency of clock is made lower) than the number of clocks in the clock CLK in generating, for example, the write voltage VPGM so as to cause the inclination θVP1 to be smaller than the inclination θPGM of the write voltage VPGM (θVP1<θVPGM) until the write pass voltage VPASS1 to be applied to the unselected word lines WL0 to WL28 and WL30 and WL31 has been reached. Shortening the time of the clock only during the first period t1-C enables the inclination θVP1 to be made smaller than the inclination θVPGM of the write voltage VPGM.

By doing this, a blunt waveform which rises almost vertically and then inclines at θVP1 until voltage VPASS1 has been reached can be generated on the unselected word lines WL0 to WL28 and WL30 and WL31. In the first embodiment, the number of clocks during period t1-C is made smaller so as to cause the inclination θVP1 of the rising of the write pass voltage VPASS1 applied to the unselected word lines WL0 to WL28 and WL30 and WL31 to be smaller than the inclination θVPGM of the rising of the write voltage VPGM (θVP1<θVPGM).

As described above, in the first embodiment, the number of clocks in the clock CLK is changed without decreasing the number of charge pump circuits 11, making it possible to generate a blunt waveform, such as output waveform (C). By changing the number of clocks in the clock CLK, variations in the characteristics of the transistors constituting the charge pump circuits 11 or variations in the characteristics of the transistors that cut off the voltages supplied from the charge pump circuits 11 can be prevented from having an adverse effect. As a result, the controllability of the charge pump circuit 11 can be improved and the output waveform (C) of the charge pump circuit 11 can be stabilized.

In addition, an n number of charge pump circuits 11 may be used at the beginning of the rising of the waveform and then the number may be decreased to n′ (n′<n).

2-5. Inclination of θVP2

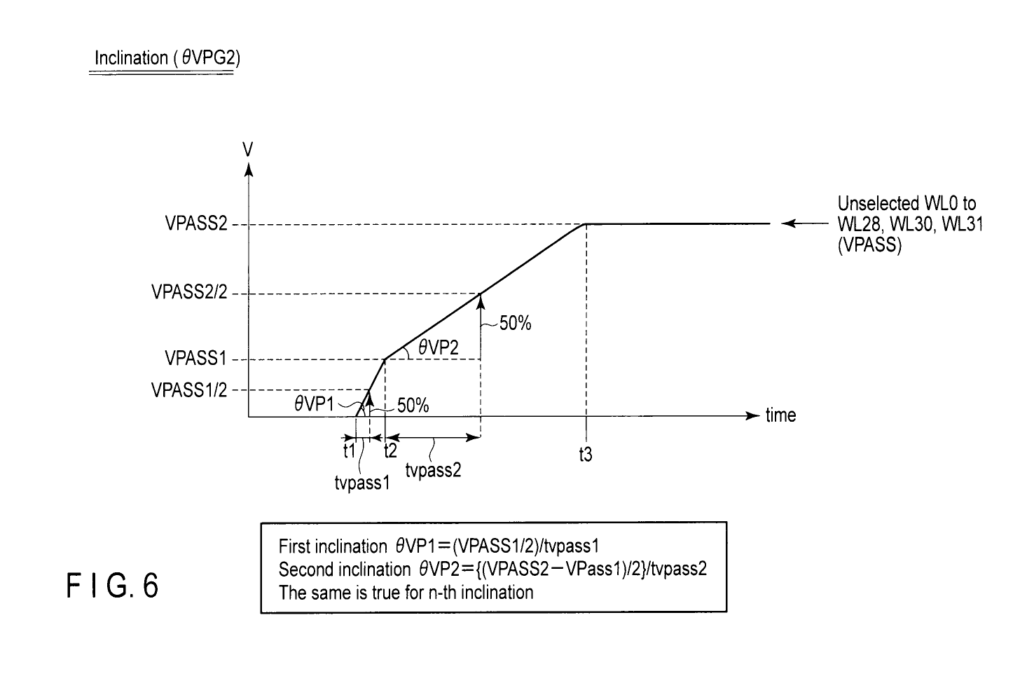

Next, the inclination θVP2 of the write pass voltage VPASS according to the first embodiment will be explained with reference to FIG. 6.

As shown in FIG. 6, the inclination θVP2 of a second rising of the write pass voltage VPASS is defined as follows in the first embodiment:

The inclination θVP2 of a second rising of the write pass voltage: {(VPASS2−VPASS1)/2}/tvpass2

The same holds true when there are more than two inclinations (or an n number of inclinations) in the write pass voltage.

A concrete example of generating voltage waveforms on the unselected word lines WL0 to WL28 and WL30 and WL31 is as follows with reference to FIG. 5.

The generation of the inclination θVP2 of the rising of the write pass voltage VPASS2 will be explained with reference to (D) in FIG. 5. To obtain output waveform (D), clock pulses CLK are generated consecutively to raise a voltage rapidly so that the voltage may rise almost vertically during period t3-C (t3-C>t1-C) until specific voltage VO has been reached. After specific voltage VPASS1 has been reached, periods t1-C and t2-C are repeated until voltage VPASS2 has been reached as in the waveform (A).

By doing this, it is possible to generate the inclination θVP2 of the rising of the write pass voltage VPASS2 smaller than the inclination θVPGM of the rising of the write voltage VPGM.

<3. Operational Advantage>

The semiconductor memory device of the first embodiment produces at least the effects described in item (1) to item (3).

(1) Helpful in Reducing Write Failures

As shown in FIG. 3, in the semiconductor memory device of the first embodiment, the controller (control circuit) 4 performs control so as to cause the inclination θVP1 of the rising to be smaller than the inclination θVPGM of the rising of the write voltage VPGM (θVP1<θVPGM) until the write pass voltage VPASS to be applied to the unselected word lines WL0 to WL28 and WL30 and WL31 has been reached.

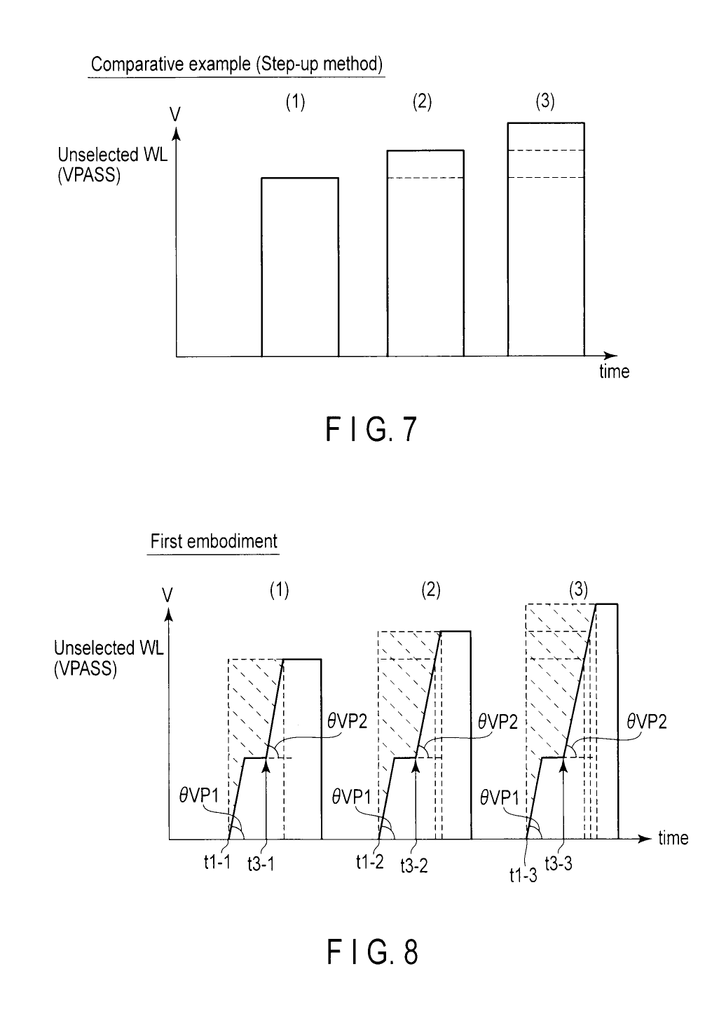

On the other hand, an unselected voltage in a step-up method related to a comparative example is as shown in FIG. 7. In FIG. 7, the write voltage VPGM is applied three times (similarly, the write pass voltage VPASS is also applied three times). As shown in FIG. 7, the unselected voltage in the comparative example is raised almost vertically to the write pass voltage VPASS in a first application (1). In a second application (2) and a third application (3), a specific stepped-up voltage is added and the unselected voltage is raised similarly. Therefore, an area of voltage (VPASS)×time cannot be decreased.

However, in the first embodiment, the write pass voltage VPASS applied to the unselected word lines WL0 to WL28 and WL30 and WL31 can be raised gently as shown in FIG. 8.

Specifically, in a first pulse (1) of FIG. 8, the voltage is raised at an inclination of θVP1 (θVP1 <θVPGM) of the rising to the write pass voltage at time t1-1 by the method explained in FIG. 5. Then, at time t3-1 after a specific time has elapsed, the voltage is raised at an inclination of θVP2 to the voltage VPASS2 by the method explained in FIG. 5.

After this, the specific voltage is raised to a stepped-up voltage with the second and third pulses (2) and (3) similarly.

As described above, as compared with a comparative example of raising the voltage almost vertically shown by broken lines in FIG. 8, an area of voltage (VPASS)×time can be decreased. As a result, a write stress on the unselected cell can be reduced, which is helpful in reducing write failures.

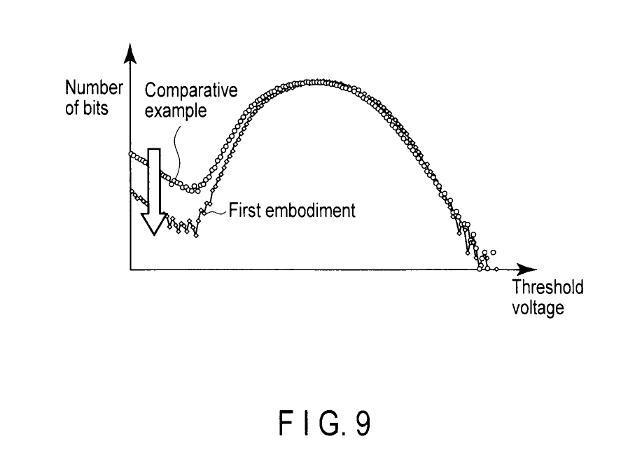

For example, a specific threshold distribution when the first embodiment is applied is predicted as shown in FIG. 9. The vertical axis of FIG. 9 indicates the number of bits (log scale) and the horizontal axis indicates a threshold voltage.

As shown in FIG. 9, the write pass voltage VPASS1 is raised gently at an inclination of θVP1, causing the number of bits in a threshold distribution adjacent to the lower limit side (or a place where the number of bits increases in the lower limit of the threshold distribution) to decrease as compared with a comparative example. This means that the number of write failures due to a write stress on unselected cells is small. Even in the first embodiment, there is a part where a threshold distribution overlaps with a threshold distribution adjacent to the lower limit side. However, there is no problem, provided that the number of write failures has been decreased to the extent that errors can be corrected by ECC or the like.

In addition, raising the write pass voltage in two stages enables the write pass voltage VPASS1 in the first stage to be made lower. As a result, a write stress on unselected cells can be reduced further, enabling write failures to be prevented more effectively.

This has the merit of improving the reliability of the entire NAND flash memory 21.

Similarly, it is clear that the number of failure bits can be decreased by raising the write pass voltage VPASS2 gentry at an inclination of θVP2 as compared with the comparative example. In addition, raising VPASS2 gently enables overshoots to be decreased and a stress on unselected cells to be reduced. Moreover, the write pass voltage VPASS1 causes the unselected cell conduct. That is, even if the write pass voltage VPASS2 is raised gently, the write time hardly gets longer.

(2) The channel potential Vchannel can be kept high, improving the reliability.

As shown in FIG. 3, in the first embodiment, at time 3, the control circuit 4 performs control so as to raise the voltages of the unselected word lines WL0 to WL28 and WL30 and WL31 to the write pass voltage VPASS2 after the voltage of the selected word line 29 has reached the write voltage VPGM.

As described above, by raising the voltages of the unselected word lines WL0 to WL28 and WL30 and WL31 to the write pass voltage VPASS2, the channel potential Vchannel2 dropped due to a boost leak can be raised again by coupling. Therefore, the substrate voltage Vchannel can be kept high, which offers the advantage of preventing the selected cell not to be written into from being written erroneously.

When the number of times writing/erasing was done is small (when the tunnel insulating film of the memory cell MC has not deteriorated), the write time (the period between t2 and t4 in FIG. 3) is relatively long. In addition, when the write threshold value is high for the memory cell MC, the write time might be made longer. When the write time becomes longer, the channel potential is more liable to drop due to a boost leak. Therefore, only when the number of times writing/erasing was performed is smaller than a specific number of times or only when the number of write loops has exceeded a specific number of loops (e.g., N loops), the write pass voltage VPASS2 may be raised in two stages.

When it is not likely that the selected cell not to be written into will be written into erroneously (or when the write threshold value for the memory cell MC is low) even if the channel potential is low, the write pass voltage VPASS can be made low. That is, only the write pass voltage VPASS1 is used without raising the write pass voltage VPASS in two stages. As a result, the possibility of the selected cell not to be written into being written into erroneously can be decreased, while reducing a stress caused by the write pass voltage VPASS on the unselected cell.

Furthermore, the write pass voltage VPASS may be changed in two stages when the number of write loops is in the range of N to M (1≦N<M), taking into account both the deterioration of the tunnel insulating film of the memory cell MC and the write threshold value for the memory cell MC. In addition, the write pass voltage VPASS may be changed in two stages only when the number of write loops is a specific number N.

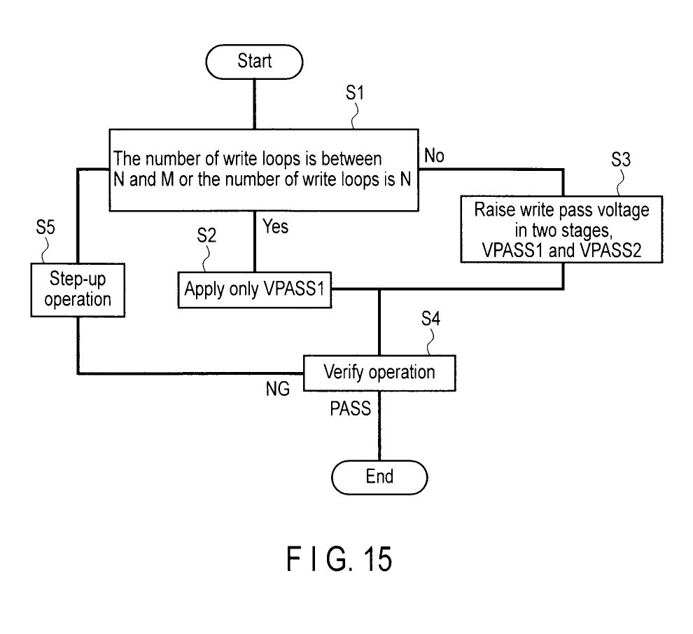

This example will be explained with reference to a flowchart shown in FIG. 15. The controller 4 determines whether the number of write loops is between N and M or is N (step S1). Here, N and M may be changed, depending on the deterioration of the tunnel insulating film of a memory cell. For example, when the number of writes/erases is stored in the ROM fuse 6. When the number of writes/erases has reached a specific number, the controller 4 changes N or M. If the number of writes/erases is between N and M or is N, a write operation is performed using only the write pass voltage VPASS1 (step S2). If the number of writes/erases is not between N and M or not is N, the controller 4 raises a write pass voltage VPASS in two stages and performs a write operation (step S3). After the write operation, the controller 4 performs a verify operation to verify whether writing has been done properly (step S4). If writing has been done properly, a series of operations is terminated. If writing has not been performed properly, the controller 4 performs a step-up operation (step S5). The step-up operation (step S5) raises the upper limits of VPGM, VPASS1, and VPASS2 by a constant value. Thereafter, control returns to step S1 and a series of operations is repeated.

(3) The controllability of voltage waveforms can be improved, enabling the voltage waveforms to be stabilized.

As shown in FIG. 5, voltage waveforms on the unselected word lines WL0 to WL28 and WL30 and WL31 can be generated in the first embodiment.

Specifically, in the first embodiment, the clock waveform input to the charge pump circuits 11 is controlled so as to cause the inclinations θVP1, θVP2 to be smaller than the inclination θVPGM of the voltage VPGM until the write pass voltage VPASS applied to the unselected word lines WL0 to WL28 and WL30 and WL31 has been reached (θVP1, θVP2<θVPGM).

As described above, in the first embodiment, the number of clocks in the clock CLK is changed without decreasing the number of step-up circuits 11, making it possible to generate a blunt voltage waveform, such as output waveform (C) or output waveform (D). Therefore, variations in the characteristics of the transistors constituting the charge pump circuits 11 or variations in the characteristics of the transistors that cut off the voltages supplied from the charge pump circuits 11 can be prevented from having an adverse effect. As a result, the controllability of output waveforms (C) and (D) can be improved, enabling the waveforms to be stabilized.

### Second Embodiment (Example of an REASB Method)

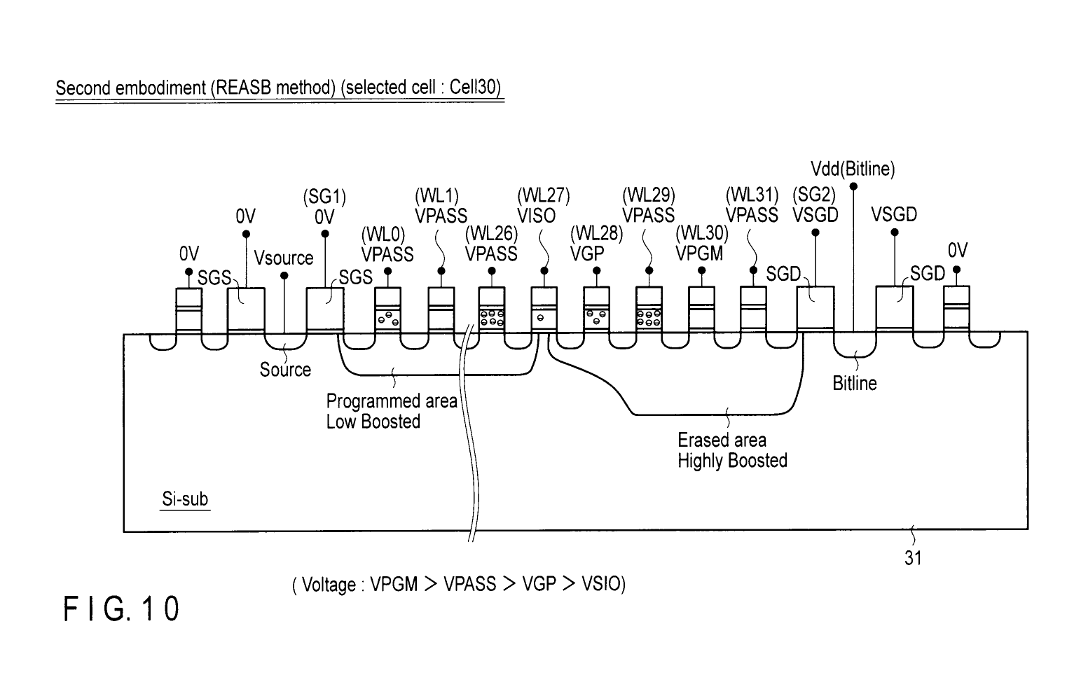

Next, a semiconductor memory device according to a second embodiment will be explained with reference to FIG. 10. The second embodiment is such that the first embodiment is similarly applied to voltages VPASS, VISO, and VGP applied to the unselected word lines WL of the unselected bit lines in a Revised Erase Area Self Boost (REASB) method. A detailed explanation of parts overlapping with the first embodiment will be omitted.

REASB method

The REASB method of the second embodiment will be explained with reference to FIG. 10.

The REASB method relates to a voltage applied to the unselected word line WL of the unselected bit line. Voltage relations are as shown in FIG. 10. In the second embodiment, the selected cell is assumed to be MC30.

As shown in FIG. 10, a voltage VPGM is applied to the selected word line WL30.

A voltage VGP is applied to an unselected word line WL28. The voltage VGP is a voltage that eases a sharp potential difference between VISO, VPASS2, and VPGM (VISO<VGP<VPASS2).

The voltage VISO is applied to unselected word line WL27 closer to the source line side than unselected word line WL30. The voltage VISO is a voltage that separates a Highly boosted area from a Low Boosted area and is a little higher than, for example, the ground potential Vss.

The voltage relations are not limited to what has been described above. For instance, the number of voltage types may be four or more or less. The number of word lines WL to which voltage VPG/voltage VISO is applied may be two.

The write pass voltages VPASS1, VPASS2 described in the first embodiment are applied to the remaining unselected word lines WL0 to WL26 and WL29 and WL31.

The above voltages satisfy the following expression: VPGM>VPASS2>VGP>VISO. VPASS1 may lie between VPASS2 and VISO and be higher or lower than or equal to VGP.

The aforementioned voltage relations form in the substrate 31 a low boosted program area and a highly boosted erased area.

With the voltages VGP, VISO of the second embodiment, too, the inclinations of the voltages can be controlled as in the first embodiment.

<Operational Advantage>

As described above, the semiconductor memory device of the second embodiment produces at least the same effects as those described in item (1) to item (3).

Furthermore, the first embodiment may be applied to the REASB method as needed as in the second embodiment. Like the write pass voltages VPASS1, VPASS2, after the voltage VGP1 is applied and the channel potential drops due to a boost leak, the channel potential is raised to a voltage VGP2 higher than the voltage VGP1, preventing the channel potential Vchannel from dropping.

### Third Embodiment (Example of Raising a Voltage in More Stages)

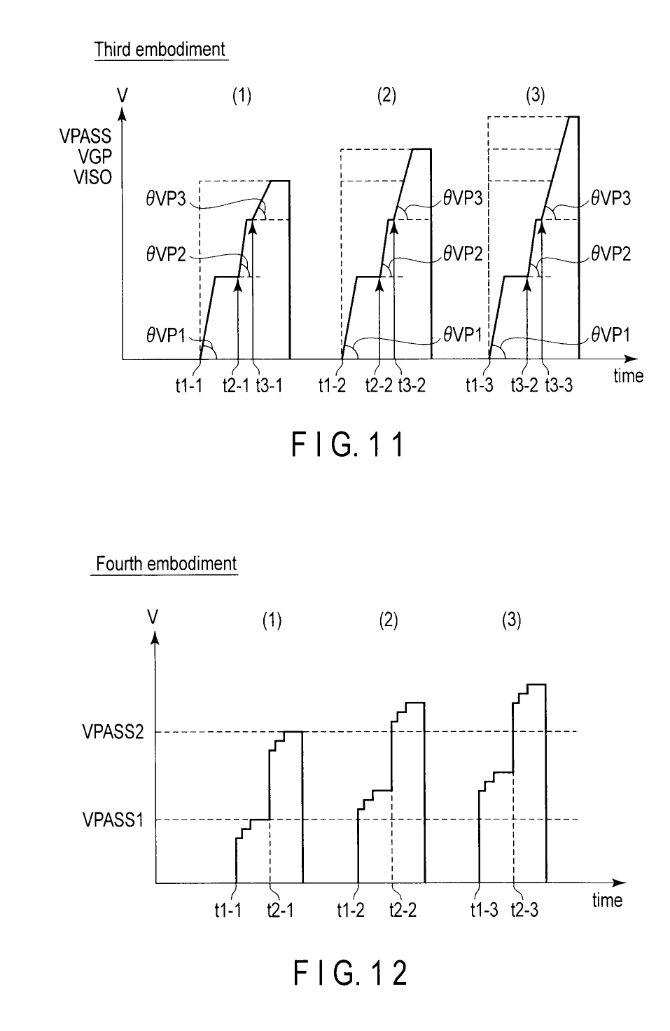

Next, a semiconductor memory device according to a third embodiment will be explained with reference to FIG. 11. The third embodiment relates to an example of raising a voltage applied to the unselected word line in more stages. A detailed explanation of parts overlapping with the first and second embodiments will be omitted.

The third embodiment will be explained briefly with reference to FIG. 11.

As shown in FIG. 11, the third embodiment differs from the second embodiment in that the voltage VPASS applied to the unselected word line WL is raised in more stages. The rise time of the unselected word line is controlled so as to be earlier than the write voltage VPGM. The voltage VPASS is raised for the second time and later after the write voltage VPGM has been applied.

Specifically, in a first pulse (1), the voltage is raised to a specific voltage (VPASS3) at an inclination of θVP3 of a third rising (θVP1, θVP2, θVP3<θVPGM) at time t3-1. Similarly, in a second and a third pulse (2) and (3), the specific voltage is raised to a stepped-up voltage at an inclination of θVP3 of the third rising at time t3-2 and at time t3-3.

These operations are repeated until the selected cell has reached a specific threshold value. The voltages VGP and VISO can be controlled similarly.

In addition, when the number of times writing/erasing was done has exceeded a specific number of times, or when the number of write loops has exceeded a specific number of loops, the write pass voltage VPASS may be raised in more than three stages. Even if the write time changes, the channel potential Vcahnnel can be kept constant.

<Operational Advantage>

The semiconductor memory device of the third embodiment produces the same effects as those described in item (1) to item (3) in the first embodiment. The third embodiment may be applied as needed. The channel potential Vhannel can be raised little by little, enabling the level of the voltage Vchannel to be made more stable.

### Fourth Embodiment (Example of Raising a Voltage Stepwise)

Next, a semiconductor memory device according to a fourth embodiment will be explained with reference to FIG. 12. The fourth embodiment relates to an example of raising a voltage applied to the unselected word line stepwise. A detailed explanation of parts overlapping with the first and second embodiments will be omitted.

The fourth embodiment will be explained briefly with reference to FIG. 12.

As shown in FIG. 12, the fourth embodiment differs from the third embodiment in that the voltages VPASS1, VPASS2 applied to the unselected word line WL are raised stepwise. The rise time of the unselected word line is controlled so as to be earlier than the write voltage VPGM. The voltage VPASS is raised to the write pass voltage VPASS2 after the write voltage VPGM has been applied.

Specifically, in a first pulse (1), at time t2-1, the voltage is raised almost vertically to the write pass voltage VPASS1 in three stages. Then, at time t3-1, the voltage is raised almost vertically to the write pass voltage VPASS2 in three stages.

Similarly, in a second and a third pulse (2) and (3), the specific voltage is raised to a stepped-up voltage. VPASS2 has been stepped up and is higher than the first pulse. The write pass voltage VPASS is raised stepwise instead of making smaller the inclination of the rising of the write pass voltage VPASS, which produces the same effect as when the inclination of the rising is made smaller.

These operations are repeated until the selected cell has reached a specific threshold value. The voltages VGP and VISO can be controlled similarly.

<Operational advantage>

The semiconductor memory device of the fourth embodiment produces the same effects as those described in item (1) and item (2). The fourth embodiment may be applied as needed. In addition, raising the write pass voltage VPASS stepwise makes it easier to control the write pass voltage VPASS.

### Fifth embodiment (Example of Raising a Voltage Stepwise)

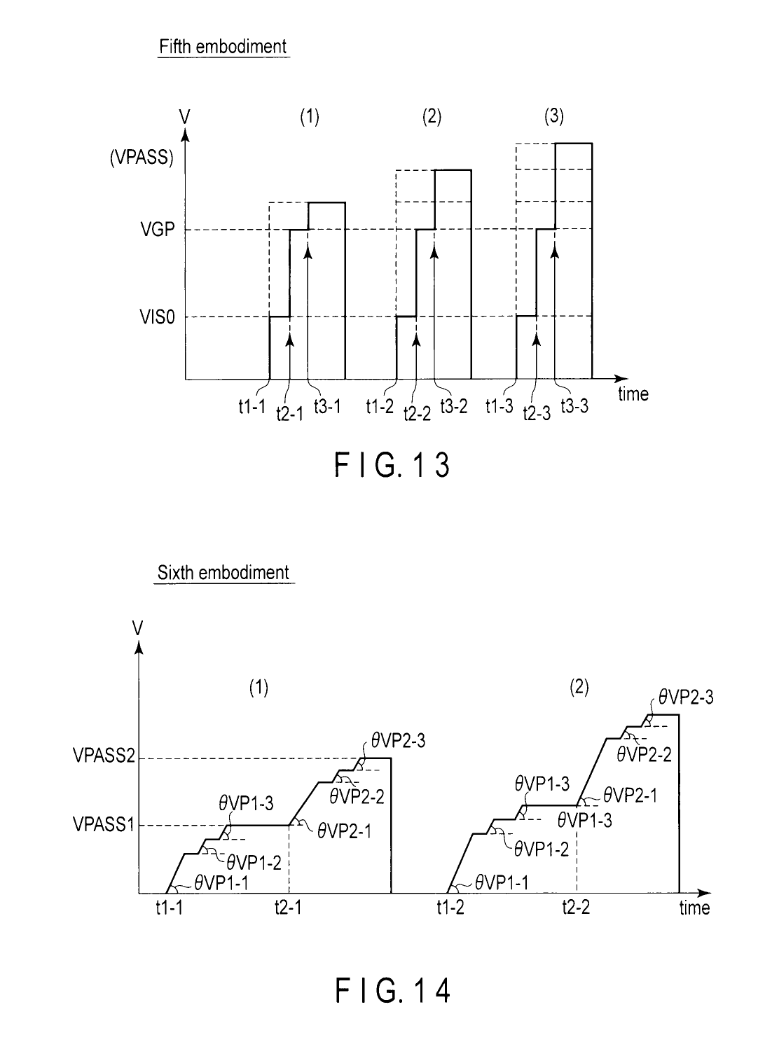

Next, a semiconductor memory device according to a fifth embodiment will be explained with reference to FIG. 13. The fifth embodiment relates to an example of raising a voltage applied to the unselected word line stepwise. A detailed explanation of parts overlapping with the first and second embodiments will be omitted.

The fifth embodiment will be explained briefly with reference to FIG. 13.

As shown in FIG. 13, the fifth embodiment is the same as the fourth embodiment in that the write pass voltages VPASS1, VPASS2 applied to the unselected word line WL are raised stepwise. The rise time of the unselected word line is controlled so as to be earlier than the write voltage VPGM. The voltage VPASS is raised to the write pass voltage VPASS2 after the write voltage VPGM has been applied. For convenience sake, an explanation will be given using an example of voltage VGP=write pass voltage VPASS1.

In a first pulse (1), the write pass voltage is raised almost vertically to voltage VISO at time t2-1 and then raised to voltage VPASS1 (voltage VGP). Then, at time t3-1, the voltage is raised to write pass voltage VPASS2. Here, unselected word lines to which voltages VISO and VGP are applied stop rising in voltage when they have reached the respective voltages and are kept at their respective voltages VSIO and VGP.

Similarly, in a second and a third pulse (2) and (3), the voltages are raised to write pass voltage VPASS2 (where the second and third pulses have been stepped up and are higher than the first one).

These operations are repeated until the selected cell has reached a specific threshold value. This modification can be realized by, for example, setting parameters recorded in the ROM fuse 6, causing the controller 4 to read the parameter, and implementing the parameters.

<Operational Advantage>

The semiconductor memory device of the fifth embodiment produces the same effects as those described in item (1) and item (2). The fifth embodiment may be applied as needed. In addition, the rising of the write pass voltage VPASS is divided by other voltages VISO and VGP, which reduces the number of voltages generated by the step-up circuits 11. As a result, the circuit operation can be simplified.

### Sixth Embodiment (Example of Raising a Voltage Gently Stepwise)

Next, a semiconductor memory device according to a sixth embodiment will be explained with reference to FIG. 14. The sixth embodiment relates to an example of raising a voltage applied to the unselected word line gently stepwise. A detailed explanation of parts overlapping with the first and second embodiments will be omitted.

The sixth embodiment will be explained briefly with reference to FIG. 14.

As shown in FIG. 14, the sixth embodiment is the same as the fourth embodiment in that the write pass voltage VPASS applied to the unselected word line WL is raised stepwise. The sixth embodiment differs from the fifth embodiment in that the write pass voltage VPASS is raised gently stepwise. The rise time of the unselected word line is controlled so as to be earlier than the write voltage VPGM. The voltage VPASS is raised to the write pass voltage VPASS2 after the write voltage VPGM has been applied.

The write pass voltage VPASS is raised at an inclination of θVP1-1 at time t2-1, then at an inclination of θVP1-2, and then at an inclination of θVP1-3 to voltage VPASS1. The inclinations θVP1-1, θVP1-2, θVP1-3 are smaller than the inclination OVPGM.

Similarly, the write pass voltage VPASS is raised at an inclination of θVP2-1 at time t3-1, then at an inclination of θVP2-2, and then at an inclination of θVP2-3 to voltage VPASS2. The inclinations θVP2-1, θVP2-2, θVP2-3 are smaller than the inclination θVPGM.

In a second pulse (2), the write pass voltage VPASS is raised similarly.

These operations are repeated until the selected cell has reached a specific threshold value.

This modification can be realized by, for example, setting parameters recorded in the ROM fuse 6, causing the controller 4 to read the parameter, and implementing the parameters.

<Operational Advantage>

The semiconductor memory device of the sixth embodiment produces the same effects as those described in item (1) and item (2). The sixth embodiment may be applied as needed. In addition, making smaller the inclinations of the rising of a stepwise pulse enables a write stress on the unselected cell to be reduced further, preventing write failures.

[Modification]

Next, a semiconductor memory device according to a modification will be explained.

The invention is not limited to the aforementioned embodiments. For instance, the embodiments may be modified variously as needed by, for example, setting parameters recorded in the ROM fuse 6 and causing the controller 4 to execute the parameters.

For example, the method of using the write pass voltage VPASS is not limited to the step-up method (the VPASS-Step Up method). For instance, a fixed method (a VPSS fixed method) may be used.

As for the pulse raising method, a pulse may be raised gently as in the first embodiment or stepwise as in the fourth embodiment.

The initial voltage of a pulse voltage, a step voltage, the number of steps, an inclination, and a length may be kept constant, changed within a waveform, or changed from one waveform to another.

In addition, only the write pass voltage VPASS may be modified or a combination of the write pass voltage VPASS and other voltages (including VISO and VGP) may be modified.

It goes without saying that the invention is not limited to these and that these may be combined as needed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array comprising a plurality of memory cell units which are arranged at intersections of a plurality of bit lines and a plurality of word lines and whose current paths are connected in series;
a voltage generator circuit which generates a voltage to be applied to the memory cell array; and
a control circuit which controls the memory cell array and the voltage generator circuit and which, when writing data into the memory cell array, performs control so as to apply a first write pass voltage to unselected word lines in the memory cell units and, after a selected word line has reached a write voltage, apply a second pass voltage higher than the first write pass voltage to the unselected word lines.

2. The semiconductor memory device of claim 1, wherein the control circuit performs control so as to make smaller a first inclination of the first write pass voltage than the inclination of the write voltage.

3. The semiconductor memory device of claim 1, wherein the control circuit performs control so as to make smaller a second inclination of the second write pass voltage than the inclination of the write voltage.

4. The semiconductor memory device of claim 1, wherein the control circuit performs control so as to raise the voltage applied to the unselected word lines in the memory cell units stepwise until the voltage has reached the first and second write pass voltages.

5. The semiconductor memory device of claim 1, further comprising a source line connected to one end of the memory cell unit,
wherein the control circuit applies an isolation voltage lower than the first write pass voltage to the unselected word lines closer to the source line side than the selected word line.

6. The semiconductor memory device of claim 2, wherein the voltage generator circuit comprises a step-up circuit to which a clock is input and a pulse generator circuit that generates a pulse voltage corresponding to the output of the step-up circuit, and
the control circuit, when writing data into the memory cell array, controls the voltage generator circuit so as to make smaller the number of clocks in generating the first write pass voltage than the number of clocks in the clock in generating the write voltage so as to make smaller the first inclination than the inclination of the write voltage.

7. A method of controlling a semiconductor memory device comprising:
applying a first write pass voltage to unselected word lines in memory cell units when data is written into a memory cell array that comprises the memory cell units which are arranged at intersections of a plurality of bit lines and a plurality of word lines and whose current paths are connected in series; and
performing control so as to apply a second pass voltage higher than the first write pass voltage to the unselected word lines after a selected word line has reached a write voltage.

8. The method of claim 7, further comprising controlling the voltage applied to the unselected word lines in the memory cell units so as to make smaller a first inclination of the first write pass voltage than the inclination of the write voltage.

9. The method of claim 7, further comprising controlling the voltage applied to the unselected word line in the memory cell units so as to make smaller a second inclination of the second write pass voltage than the inclination of the write voltage.

10. The method of claim 7, further comprising performing control so as to raise the voltage applied to the unselected word lines in the memory cell units stepwise until the voltage has reached the first and second write pass voltages.

11. The method of claim 7, further comprising, in an REASB method, performing control so as to apply a first write pass voltage to unselected word lines in the memory cell units connected to unselected bit lines and, after the selected word line has reached a write voltage, further apply a voltage to the unselected word lines until a second write pass voltage higher than the first write pass voltage has been reached.

12. The method of claim 7, wherein the semiconductor memory device further comprises a voltage generator circuit that generates a voltage to be applied to the memory cell array, and
a control circuit that controls the memory cell array and the voltage generator circuit.

13. The method of claim 12, wherein the voltage generator circuit comprises a step-up circuit to which a clock is input and a pulse generator circuit that generates a pulse voltage corresponding to the output of the step-up circuit, and
the control circuit, when writing data into the memory cell array, controls the voltage generator circuit so as to make smaller the number of clocks in generating the first write pass voltage than the number of clocks in the clock in generating the write voltage so as to make smaller the first inclination than the inclination of the write voltage.
